(19) United States
(12) Patent Application Publication
(10) Pub. No.: US 2017/0250315 A1
(43) Pub. Date: Aug. 31, 2017

(54) DOT MATRIX LIGHT-EMITTING DIODE BACKLIGHTING LIGHT SOURCE FOR A WAFER-LEVEL MICRODISPLAY AND METHOD FOR FABRICATING THE SAME

(71) Applicant: TREND LIGHTING CORP., Taoyuan City (TW)

(72) Inventors: Jonathan WANG, Somerset, NJ (US); Peichin HSIEH, Taoyuan City (TW); Pei-Jih WANG, Taoyuan City (TW); Shih-Chieh CHENG, Taoyuan City (TW)

(73) Assignee: TREND LIGHTING CORP., Taoyuan City (TW)

(21) Appl. No.: 15/439,574

(22) Filed: Feb. 22, 2017

(30) Foreign Application Priority Data
Feb. 26, 2016 (TW) 105105798

(51) Int. Cl. H01L 33/40; H01L 33/60; H01L 33/62; H01L 33/46

(52) U.S. Cl. CPC H01L 33/405; H01L 33/46; H01L 33/60; H01L 33/62

(57) ABSTRACT

A dot matrix light-emitting diode (LED) backlighting light source for a wafer-level microdisplay includes a substrate and a bonding layer, multiple LEDs arranged at intervals, a first electrode assembly, and a second electrode assembly sequentially formed on a top surface of the substrate. The first electrode assembly and the second electrode assembly are connected in series to the multiple LEDs to constitute a dot matrix LED light source, which allows to be directly packaged and assembled in a microdisplay in production and is advantageous in reduced size and lower production.

### BACKGROUND OF THE INVENTION

1. Field of the Invention

The present invention relates to a microdisplay and, more particularly, to a dot matrix light-emitting diode (LED) backlighting light source for a wafer-level microdisplay and a method for fabricating the same.

2. Description of the Related Art

To disseminate, exchange and store information, human utilizes means as media for documents, such as inscribed stone and bamboo slips way back in ancient times and paper in more recent times. Technological breakthrough and rapid development of society allow early-stage displays to be born in 1922, enabling the ways of information dissemination to migrate from static texts to dynamic pictures of images and videos. Those early-stage displays adopt raster scan theory of cathode ray tube (CRT), which turned a new page back then in terms of information dissemination.

However, CRT displays have the issues of being bulky and taking up too much space. Such size issue failed to be successfully tackled with numerous attempts been made until liquid crystal displays were introduced. As liquid crystal materials are not self-illuminating, a backlight source is required for liquid crystal displays (LCD) to display information. Shortly, the following development of light-emitting diode (LED) has brought forth revolutionary changes to lighting industry. In view of the advantages in small size, high luminance and high lighting efficiency, LEDs have been used as the backlight sources for LCDs, small displays and projectors.

Current technology involved with an LED light source can be implemented on a substrate, such as sapphire, gallium arsenide (GaAs) and gallium phosphide (GaP) substrates. An epitaxial layer is deposited on the substrate by an epitaxy growth methods, such as metal organic chemical vapor deposition (MOCVD), vapor phase epitaxy (VPE), liquid phase epitaxy (LPE) or molecular beam epitaxy (MBE). The epitaxial layer can be divided into multiple LEDs spaced apart from each other by a photolithography process, an etching process, a lift-off process, a thin film deposition process, an alloy process and a metal deposition process for each LED to be equipped with electrodes for conducting power and packaging. A grinding process is further applied to thin the thickness of the substrate, a dicing process is applied to cut the multiple LEDs into multiple LED dices, and a packaging process is applied to the LED light source.

The foregoing photolithography process includes coating, exposure and development processes and serves to generate a photoresist layer on a surface of the epitaxial layer, a surface of a thin film or a surface of a thin metal film. The photoresist layer is formed by a photosensitive material. The exposure process serves to print a pattern of a mask having spaces arranged at intervals on the photoresist layer. The etching process first etches away portions of the epitaxial layer not covered by the photoresist layer and then removes the photoresist layer for the epitaxial layer to form multiple LEDs spaced apart from each other by gaps, the thin film to form a pattern with spaces arranged at intervals, or the thin metal film to form a pattern with spaces arranged at intervals. The lift-off process removes the photoresist layer with an organic chemical solution for the thin metal film grown on the photoresist layer to be removed and portions of the thin metal film not covered by the photoresist layer to remain. The etching process may be a dry etching process or a wet etching process. Specifically, the dry etching process is an inductively coupled plasma reactive ion etching (ICP-RIE) and the wet etching process utilizes a chemical solution to perform etching via chemical reaction. The thin film deposition process deposits thin metal film on the multiple LEDs, and the photolithography process and the etching process are further applied to form electrodes. The thin film deposition process targets at growing non-metal thin film on surfaces of the multiple LEDs or portions among the multiple LEDs, and the photolithography process and the etching process are further applied to remove unnecessary portions of the thin film to serve the purpose of insulation, support or electrical conduction depending on the nature of the thin film. The alloy process forms good ohmic contact between the electrodes and the LEDs for electrical conduction through high-temperature baking.

There is another one conventional LED light source, which has an epitaxial layer formed on a first substrate. The LED wafer fabrication process develops multiple LEDs on the epitaxial layer. A wafer bonding process bonds the multiple LEDs to a second substrate, which is highly thermally and electrically conductive or even transparent. A laser lift-off process is further applied to remove the first substrate to enhance efficacy of the multiple LEDs in operation, a grinding process is applied to thin the second substrate, the dicing process separates multiple LED dies from the wafer, and the packaging process packages the multiple LED dies to form the LED light source

Most LED light sources arranged in current LED displays take the form of arrays, such as seven-segment displays, dot matrix displays or regular LCD displays. As usually tending to be relatively large in size and limited by requirements of working accuracy for positioning and spatial arrangement, the packaged LED light sources are not applicable to small displays or are applicable to displays with limitations in size and the number of LED light sources equipped, which compromise display performance and operational convenience. Additionally, production cost of the LED array displays inevitably increase due to the array assembly processes.

### SUMMARY OF THE INVENTION

An objective of the present invention is to provide a dot matrix light-emitting diode (LED) backlighting light source for a wafer-level microdisplay and a method for fabricating the same, which allow multiple LEDs connected in series to constitute a dot matrix LED light source to attain to be small in size and low in production cost without requiring additional processes in dicing, packaging and assembly.

To achieve the foregoing objective, the dot matrix LED backlighting light source for a wafer-level microdisplay includes a substrate, an LED epitaxial layer, a bonding layer, a first electrode assembly, and a second electrode assembly.

The LED epitaxial layer is formed on a top surface of the substrate and has multiple LEDs arranged at intervals to take the form of a matrix.

The bonding layer is formed between the top surface of the substrate and bottom surfaces of the multiple LEDs.

The first electrode assembly is formed between the bottom surfaces of the multiple LEDs and a top surface of the bonding layer.

The second electrode assembly is formed on top surfaces of the multiple LEDs.

The first electrode assembly is connected in series to the multiple LEDs in a horizontal direction and the second electrode assembly is connected in series to the multiple LEDs in a vertical direction perpendicular to the horizontal direction.

From the foregoing description, manufacturers of microdisplays can connect the first electrode assembly and the second electrode assembly to the multiple LEDs that are arranged at intervals to constitute a dot matrix LED light source, which can be directly packaged and assembled in a wafer-level microdisplay. As there is no additional dicing, packaging and array assembly involved for producing the microdisplay, the microdisplay can be implemented at a reduced size and lower production cost.

To achieve the foregoing objective, a method for fabricating a dot matrix LED backlighting light source for a wafer-level microdisplay includes:

providing a first substrate;

growing an LED epitaxial layer on a bottom surface of the first substrate;

forming multiple LEDs out of the LED epitaxial layer through an LED wafer fabrication process;

forming a first electrode assembly on bottom surfaces of the multiple LEDs;

providing a second substrate;

forming a bonding layer on a top surface of the second substrate;

bonding the first electrode assembly of the first substrate to the bonding layer of the second substrate;

removing the first substrate; and

forming a second electrode assembly on top surfaces of the multiple LEDs.

The foregoing fabrication method is involved with fabrication processes of forming the multiple LEDs and the first electrode assembly on the first substrate, using a wafer bonding process to bond the second substrate to the first electrode assembly of the first substrate, removing the first substrate, and forming the second electrode assembly on the multiple LEDs, which produce a dot matrix LED backlighting light source to be directly packaged and assembled in a wafer-level microdisplay. As there is no additional dicing, packaging and array assembly involved for producing the microdisplay, the foregoing fabrication method ensures manufacture of a microdisplay advantageous in size and production cost reduction.

Other objectives, advantages and novel features of the invention will become more apparent from the following detailed description when taken in conjunction with the accompanying drawings.

### BRIEF DESCRIPTION OF THE DRAWINGS

FIG. 1 is a top view of a first embodiment of a dot matrix LED backlighting light source for a wafer-level microdisplay in accordance with the present invention;

FIG. 2 is a cross-sectional view of the dot matrix LED backlighting light source in FIG. 1;

FIG. 3 is a cross-sectional view of the dot matrix LED backlighting light source in FIG. 2 fabricated under a first fabrication process;

FIG. 4 is a cross-sectional view of the dot matrix LED backlighting light source in FIG. 2 fabricated under a second fabrication process;

FIG. 5 is a cross-sectional view of the dot matrix LED backlighting light source in FIG. 2 fabricated under a third fabrication process; FIG. 6 is a cross-sectional view of the dot matrix LED backlighting light source in FIG. 2 fabricated under a fourth fabrication process;

FIG. 7 is a cross-sectional view of the dot matrix LED backlighting light source in FIG. 2 fabricated under a fifth fabrication process;

FIG. 8 is a cross-sectional view of the dot matrix LED backlighting light source in FIG. 2 fabricated under a sixth fabrication process;

FIG. 9 is another top view of the dot matrix LED backlighting light source for a wafer-level microdisplay in FIG. 1 being fabricated by the sixth fabrication process in FIG. 8;

FIG. 10 is a top view of a second embodiment of a dot matrix LED backlighting light source for a wafer-level microdisplay in accordance with the present invention;

FIG. 11 is a cross-sectional view of the dot matrix LED backlighting light source for a wafer-level microdisplay in FIG. 10; and

FIG. 12 is a top view of a third embodiment of a dot matrix LED backlighting light source for a wafer-level microdisplay in accordance with the present invention.

### DETAILED DESCRIPTION OF THE INVENTION

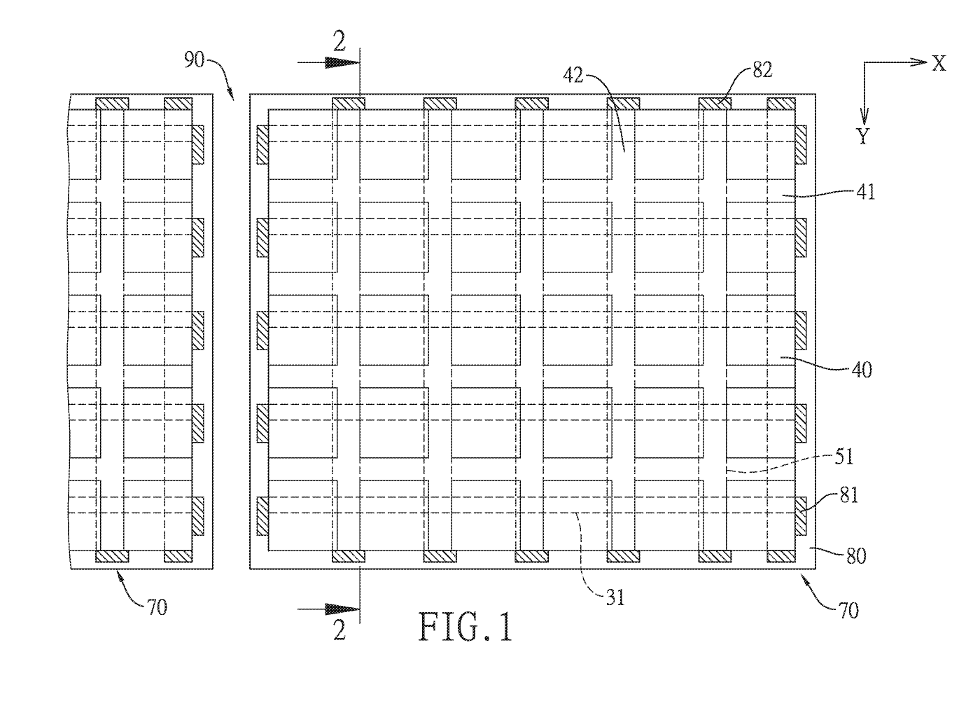

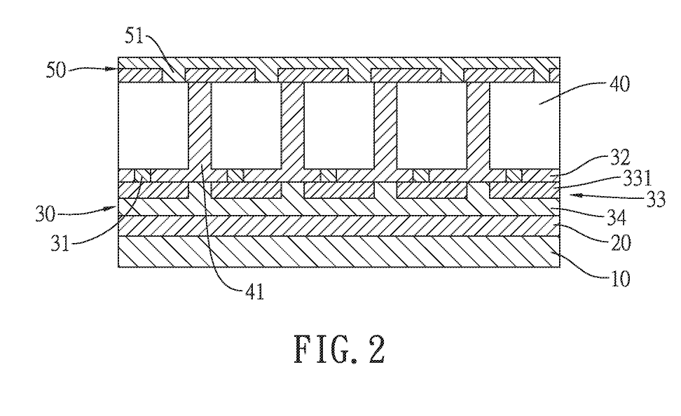

With reference to FIGS. 1 and 2, a first embodiment of a dot matrix light-emitting diode (LED) backlighting light source 70 for a wafer-level microdisplay in accordance with the present invention includes a first substrate 10, a bonding layer 20, a first electrode assembly 30, an LED epitaxial layer, and a second electrode assembly 50.

The bonding layer 20 is formed on a top of the first substrate 10. The first electrode assembly 30 is formed on a top of the bonding layer 30 and has a second insulation layer 34, a reflective layer 33, multiple first electrodes 31, and a first insulation layer 32. The second insulation layer 34 is formed on a top of the bonding layer 30. The reflective layer 33 is formed on a top of the second insulation layer 34 and has multiple reflective strips 331 parallelly arranged at intervals and extending along the X-axis direction. The multiple first electrodes 31 are respectively formed on the multiple reflective strips 331 of the reflective layer 33 and are parallelly arranged at intervals and extending along the X-axis direction. The first insulation layer 32 is formed on tops of the second insulation layer 34 and the reflective layer 33 with the multiple first electrodes 31 embedded in the first insulation layer 32. The LED eptaxial layer is formed on a top surface of the first insulation layer 32 and has multiple LEDs 40 arranged at intervals on the top surface of the first insulation layer 32 to take the form of a matrix. Each first electrode 31 is connected in series to a corresponding row of the multiple LEDs 40 arranged in the X-axis direction. The second electrode assembly 50 has multiple second electrodes 51 parallelly arranged at intervals and extending along the Y-axis direction. Each second electrode 51 is formed on and connected in series to a column of LEDs arranged in the Y-axis direction.

To facilitate the subsequent packaging processes of the backlighting light source 70, a packaging area 80 is further formed around the multiple LEDs 40 and has two first edge portions oppositely located in the X-axis direction and two second edge portions oppositely located in the Y-axis direction. Two first electrode terminals 81 are respectively formed on the two first edge portions and are respectively connected to two ends of each first electrode 31. Two second electrode terminals 82 are respectively formed on the two second edge portions and are respectively connected to two ends of each second electrode 51. In the present embodiment, a scribe line 90 is formed between each adjacent two backlighting light sources 70, and a dicing process is applied to separate each backlighting light source 70 to ease packaging of the backlighting light source 70.

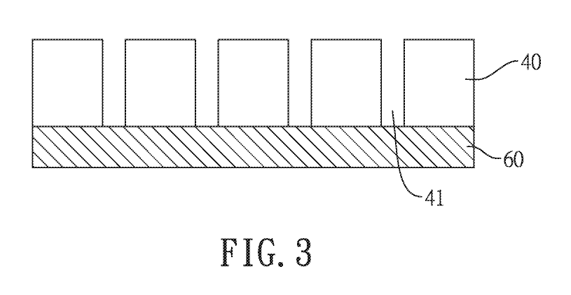

With reference to FIGS. 1 and 3, a method for fabricating a dot matrix LED backlighting light source for a wafer-level microdisplay in accordance with the present invention includes growing an LED epitaxial layer on a bottom surface of a second substrate 60, and forming multiple LEDs 40 out of the LED epitaxial layer through an LED wafer fabrication process. The multiple LEDs 40 are arranged at intervals to take the form of a matrix. A horizontal slot 41 is formed between two adjacent rows of LEDs 40, and a vertical slot 42 is formed between two adjacent columns of LEDs 40. In the present embodiment, the LED wafer fabrication process combines a photolithography process, an etching process, a lift-off process, a thin film deposition process, a coating process, a wafer bonding process, a laser lift-off process, a metal deposition process, and an alloy process. It is the photolithography process and the etching process enabling the multiple LEDs 40 that are arranged at intervals to be developed from the LED epitaxial layer. In the present embodiment, a size of each LED ranges from 1 μm˜500 μm, and the LED epitaxial layer may be an epitaxial layer of aluminum gallium arsenide (AlGaAs), gallium arsenide phosphide (GsAsP), gallium phosphide (GaP), or aluminum gallium indium phosphide (AlGaInP).

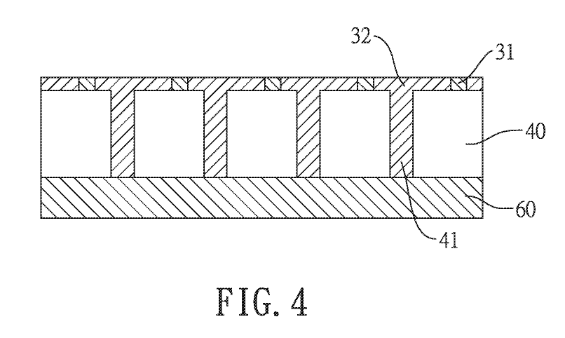

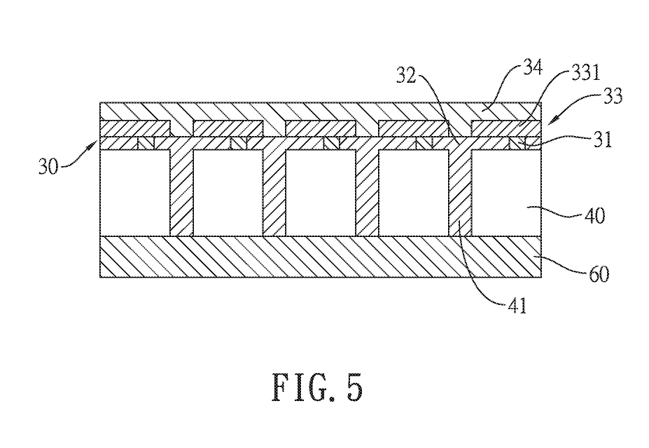

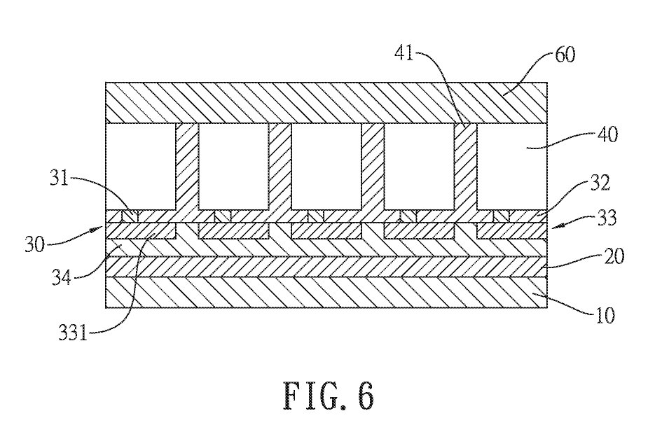

With reference to FIGS. 4 and 5, the first insulation layer 32 is formed inside the horizontal channels 41 and the vertical channels 42 and on a bottom surface of the multiple LEDs 40 by the thin film deposition process, the photolithography process and the etching process, to protect the multiple LEDs 40, keep the multiple LEDs 40 insulated from each other, hold the multiple LEDs 40 in place, and expose a part of the bottom surface of each LED 40. The first insulation layer 32 may be formed of a silicon dioxide (SiO₂) material or a silicon nitride (SiN_{X}) material.

With further reference to FIGS. 1 and 4, the multiple first electrodes 31 are respectively formed on the exposed parts of the bottom surfaces of the multiple LEDs 40 to connect each row of the multiple LEDs 40 in series in the X-axis direction by the metal deposition process, the photolithography process and the lift-off process. The multiple first electrodes 31 may be formed of an electrically conducting material, such as titanium, titanium alloy, aluminum, aluminum alloy, gold, gold alloy, platinum, platinum alloy, indium tin oxide (ITO), Zinc oxide (ZnO), or transparent conductive oxide (TCO).

With further reference to FIG. 5, the reflective layer 33 is formed on the multiple first electrodes 31 and the first insulation layer 32 by the metal deposition process, the photolithography process and the etching process. The reflective layer may include multiple reflective strips 331 parallelly arranged at intervals in the X-axis direction to cover the respective rows of the multiple LEDs in the X-axis direction, such that light emitted from the multiple LEDs 40 can be reflected upwards by the reflective layer 33. The second insulation layer 34 is formed on bottom surfaces of the reflective layer 33 and the first insulation layer 32 to protect the reflective layer 33, and a bottom surface of the second insulation layer 34 is kept flat. The second insulation layer 34 may be formed of a transparent and insulating material, such as silicon dioxide, silicon nitride and the like. The reflective layer 33 may be formed of a metal material with high reflectivity, such as gold, silver, aluminum or the like, or may be a Distributed Bragg Reflector (DBR).

With reference to FIG. 6, a first substrate 10 is prepared and a bonding layer 20 is bonded to a top surface of the first substrate 10 by the metal deposition process, the thin film deposition process or the coating process, and the second insulation layer 34 is bonded to the bonding layer 30 through the wafer bonding process. The second substrate 60 is removed by the laser lift-off process or the etching process and top surfaces of the multiple LEDs 40 and the first insulation layer 32 are exposed. The bonding layer 20 may be formed of indium, indium alloy, tin, tin alloy, gold, gold alloy, aluminum, aluminum alloy, bzocyclobutene, spin on glass (SOG) or the like. The first substrate 10 may be formed of a material with higher heat dissipation, such as silicon, aluminum nitride (AlN), aluminum oxide (Al₂O₃) or may be a metal substrate.

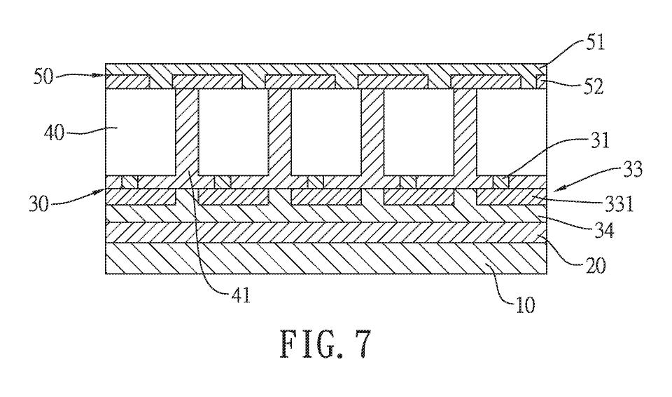

With reference to FIGS. 1 and 7, the second electrode assembly 50 includes multiple second electrodes 51 and a first isolation layer 52. The first isolation layer 52 is formed on the top surfaces of the multiple LEDs 40 and the first insulation layer 32 with a part of the top surface of each LED 40 exposed by the thin film deposition process and the photolithography process to keep the multiple second electrodes 51 in place and insulated. The multiple second electrodes 51 are formed on the exposed parts of the top surfaces of the multiple LEDs 40 and on the first isolation layer 52 by the metal deposition process, the photolithography process and the lift-off process to cover and connect the respective columns of the multiple LEDs 40 in the Y-axis direction in series. As the multiple second electrodes 51 respectively cover the multiple vertical slots 42, light emitted from the multiple LEDs 40 can be prevented from penetrating through the multiple vertical slots 42, thereby effectively concentrating light emitted from the multiple LEDs 40. Good electrical conductivity between the multiple first electrodes 31 and the multiple LEDs 40 as well as between the multiple second electrodes 51 and the multiple LEDs 40 is ensured by the alloy process. Each second electrode 51 may be formed of an electrically conducting material, such as titanium, titanium alloy, aluminum, aluminum alloy, gold, gold alloy, platinum, platinum alloy, ITO, ZnO, TCO or the like. The first isolation layer 52 may be formed of a transparent and insulating material, such as SiO2, SiN or the like.

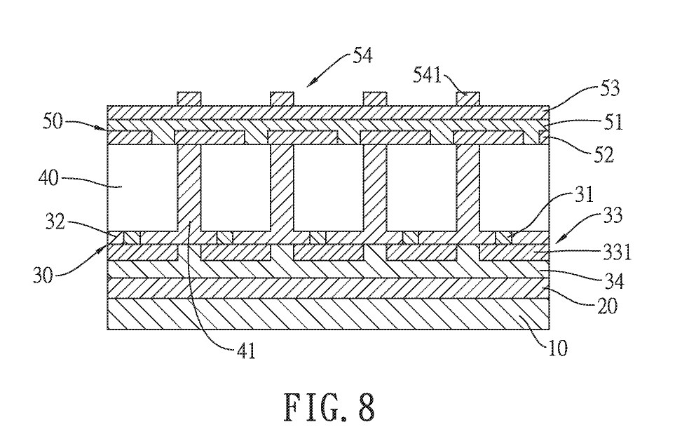

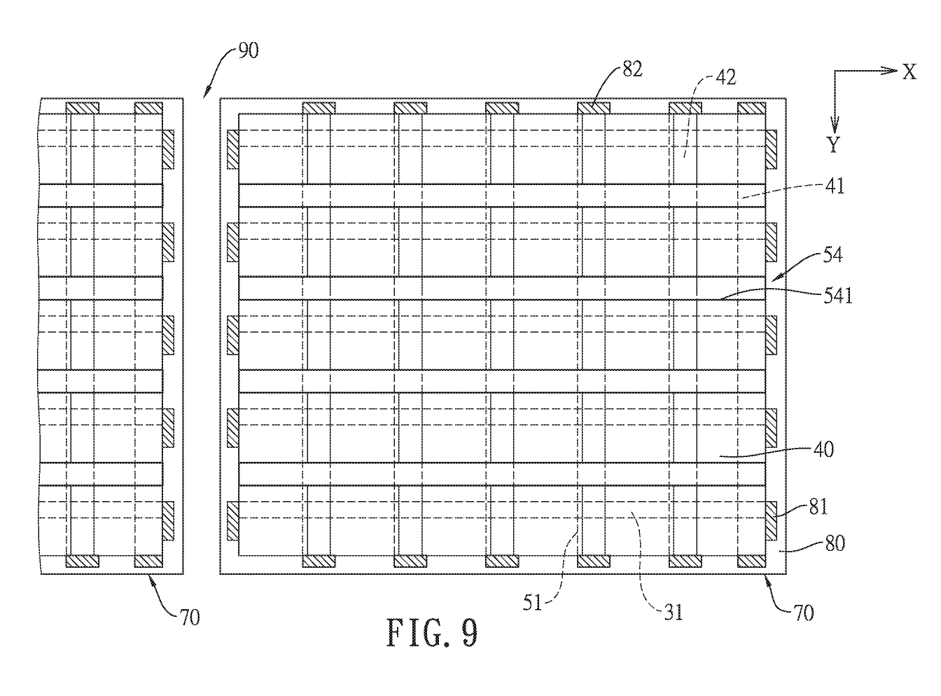

With reference to FIGS. 8 and 9, the dot matrix light-emitting diode (LED) backlighting light source 70 further includes a second isolation layer 53 and a grating layer 54 sequentially formed on a top surface of the multiple second electrodes 51. The second isolation layer 52 is formed on the top surface of the multiple second electrodes 51 to protect the multiple second electrodes 51 and keep the grating layer 54 in place by the thin film deposition process and the photolithography process. The grating layer 54 is formed on a top surface of the second isolation layer 53 by the metal deposition process, the photolithography process and the etching process and includes multiple grating members 541 arranged at intervals and covering the respective horizontal slots 41, such that light emitted from the multiple LEDs 40 can be prevented from penetrating through the multiple horizontal slots 41 thereby effectively concentrating light emitted from the multiple LEDs 40. The second isolation layer 53 may be formed of a transparent and insulating material, such as a SiO₂ material or a SiN_{X} material. The grating layer 54 is formed of a non-transparent material.

The multiple first electrodes 31 and the multiple second electrodes 51 are connected with the multiple LEDs 40 in series in the X-axis direction and the Y-axis direction respectively to constitute the dot matrix LED backlighting light source 70. During fabrication, the dot matrix LED backlighting light source 70 just needs to be directly packaged in a microdisplay to form a wafer-level microdisplay without requiring to separate the multiple LEDs into individual LEDs and then package and assemble the individual LEDs. Accordingly, cost required for dicing the multiple LEDs 40 can be reduced, and the overall size of the microdisplay is effectively lowered to facilitate subsequent assembly because no additional package and assembly of LED arrays are required.

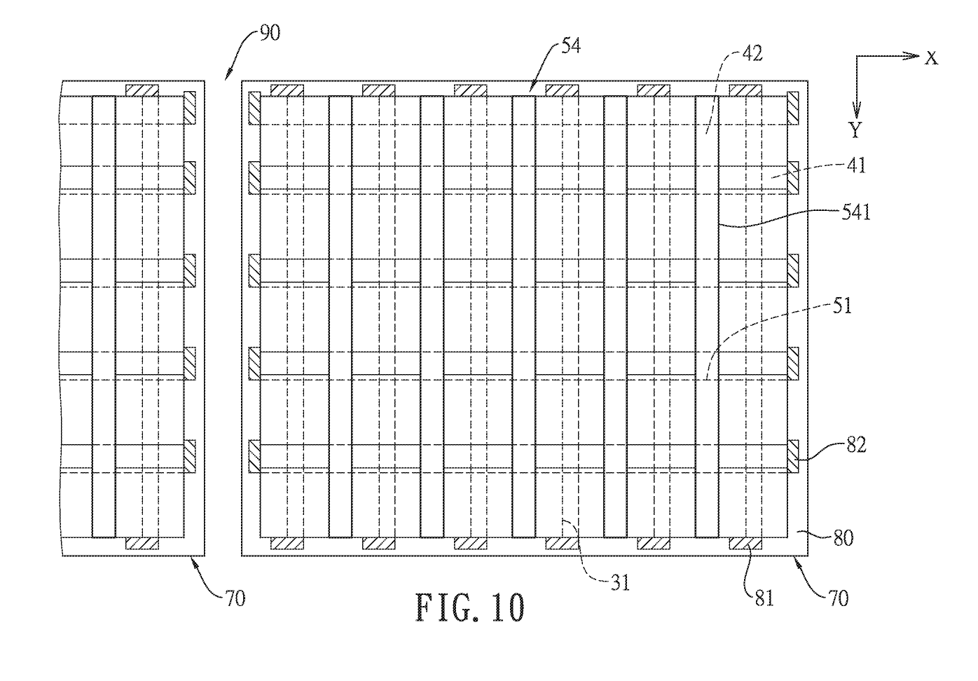

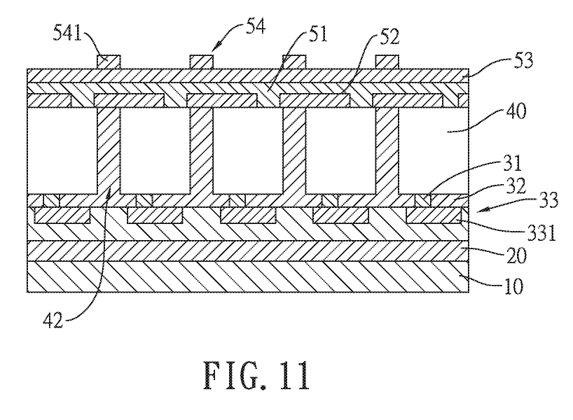

With reference to FIGS. 10 and 11, a second embodiment of a dot matrix light-emitting diode (LED) backlighting light source 70 for a wafer-level microdisplay in accordance with the present invention differs from the first embodiment in the directions with which the first electrodes 31, the second electrodes 51, the grating members 541 of the grating layer 54, and the reflective strips 331 of the reflective layer 33 are aligned, and locations of the first electrode terminals 81 and the second electrode terminals 82 of the packaging area 80. In the present embodiment, each first electrode 31 is connected a corresponding column of the multiple LEDs 40 in series in the Y-axis direction, the first electrode terminals 81 are formed on the two second edge portions of the packaging area 80 and are connected to the respective first electrodes 31, each second electrode 51 is connected to a corresponding row of the multiple LEDs 40 in series in the X-axis direction, and the second electrode terminals 82 are formed on the two first edge portions of the packaging area 80 and are connected to the respective second electrodes 51. Besides, each second electrode 51 blocks a corresponding horizontal slot 41, and each grating member 541 of the grating layer 54 blocks a corresponding vertical slot 42, and the reflective strips of the reflective layer 33 covers the columns of the multiple LEDs 40 in the Y-axis direction.

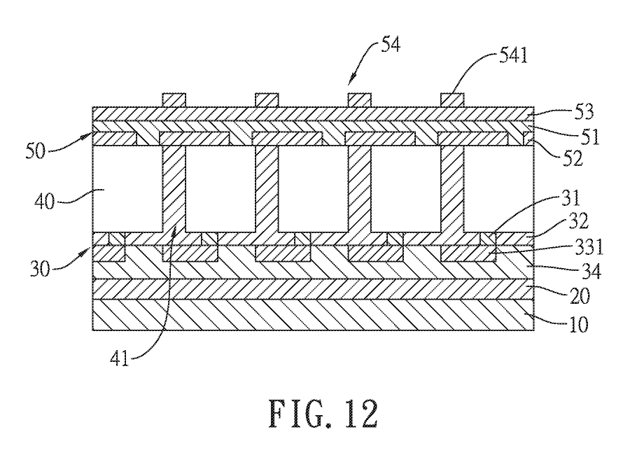

With reference to FIGS. 1 and 12, a third embodiment of a dot matrix light-emitting diode (LED) backlighting light source 70 for a wafer-level microdisplay in accordance with the present invention differs from the first embodiment in the directions of the reflective strips 331 of the reflective layer 33 are aligned. In the present embodiment, the reflective strips 331 of the reflective layer 33 blocks the respective horizontal slots 41 and can act as a grating, such that light emitted from the multiple LEDs 40 can be prevented from penetrating through the multiple horizontal slots 41, thereby effectively concentrating light emitted from the multiple LEDs 40. As the first substrate 10 is transparent, most light emitted from the multiple LEDs 40 can be seen from a top and a bottom of the backlighting light source 70.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A dot matrix light-emitting diode (LED) backlighting light source for a wafer-level microdisplay, comprising:
a substrate;
an LED epitaxial layer formed on a top surface of the substrate and having multiple LEDs arranged at intervals to take the form of a matrix;
a bonding layer formed between the top surface of the substrate and bottom surfaces of the multiple LEDs;
a first electrode assembly formed between the bottom surfaces of the multiple LEDs and a top surface of the bonding layer; and
a second electrode assembly formed on top surfaces of the multiple LEDs;
wherein the first electrode assembly is connected in series to the multiple LEDs in a horizontal direction and the second electrode assembly is connected in series to the multiple LEDs in a vertical direction perpendicular to the horizontal direction.

2. The dot matrix LED backlighting light source as claimed in claim 1, wherein the multiple LEDs takes the form of a dot matrix and are arranged to have multiple rows aligned in the horizontal direction and multiple columns in the second direction, a horizontal slot is formed between each adjacent two of the multiple rows of the multiple LEDs, and a vertical slot is formed between each adjacent two of the multiple columns of the multiple LEDs.

3. The dot matrix LED backlighting light source as claimed in claim 2, wherein the first electrode assembly has:
a second insulation layer formed on the top surface of the bonding layer;
a reflective layer formed on a top surface of the second insulation layer;
multiple first electrodes formed on a top surface of the reflective layer, parallelly arranged at intervals and extending along the horizontal direction, and connected to the respective rows of the multiple LEDs; and
a first insulation layer formed on the tops of the second insulation layer and the reflective layer with the multiple first electrodes embedded in the first insulation layer.

4. The dot matrix LED backlighting light source as claimed in claim 3, wherein the second electrode assembly has:
a first isolation layer formed on the top surfaces of the multiple LEDs and the first insulation layer with a part of the top surface of each LED exposed; and
multiple second electrodes formed on the exposed parts of the top surfaces of the multiple LEDs and on the first isolation layer and connected to the respective columns of the multiple LEDs.

5. The dot matrix LED backlighting light source as claimed in claim 4, further comprising a second isolation layer and a grating layer sequentially formed on top surfaces of the multiple second electrodes, wherein the grating layer covers the multiple horizontal slots.

6. The dot matrix LED backlighting light source as claimed in claim 5, wherein a packaging area is formed around the multiple LEDs and has two first edge portions oppositely located in the horizontal direction and two second edge portions oppositely located in the vertical direction, two first electrode terminals are respectively formed on the two first edge portions and are respectively connected to two ends of each first electrode of the first electrode assembly, and two second electrode terminals are respectively formed on the two second edge portions and are respectively connected to two ends of each second electrode of the second electrode assembly.

7. The dot matrix LED backlighting light source as claimed in claim 2, wherein the first electrode assembly has:
a second insulation layer formed on the top surface of the bonding layer;
a reflective layer formed on a top surface of the second insulation layer;
multiple first electrodes formed on a top surface of the reflective layer, parallelly arranged at intervals and extending along the vertical direction, and connected to the respective columns of the multiple LEDs; and
a first insulation layer formed on the tops of the second insulation layer and the reflective layer with the multiple first electrodes embedded in the first insulation layer.

8. The dot matrix LED backlighting light source as claimed in claim 7, wherein the second electrode assembly has:
a first isolation layer formed on the top surfaces of the multiple LEDs and the first insulation layer with a part of the top surface of each LED exposed; and
multiple second electrodes formed on the exposed parts of the top surfaces of the multiple LEDs and on the first isolation layer and connected to the respective rows of the multiple LEDs.

9. The dot matrix LED backlighting light source as claimed in claim 8, further comprising a second isolation layer and a grating layer sequentially formed on a top surface of the multiple second electrodes, wherein the grating layer covers the multiple horizontal slots.

10. The dot matrix LED backlighting light source as claimed in claim 9, wherein a packaging area is formed around the multiple LEDs and has two first edge portions oppositely located in the horizontal direction and two second edge portions oppositely located in the vertical direction, two first electrode terminals are respectively formed on the two first edge portions and are respectively connected to two ends of each first electrode of the first electrode assembly, and two second electrode terminals are respectively formed on the two second edge portions and are respectively connected to two ends of each second electrode of the second electrode assembly.

11. The dot matrix LED backlighting light source as claimed in claim 4, wherein the reflective layer has multiple reflective strips blocking the respective horizontal slots.

12. The dot matrix LED backlighting light source as claimed in claim 11, further comprising a second isolation layer and a grating layer sequentially formed on top surfaces of the multiple second electrodes, wherein the grating layer covers the multiple horizontal slots.

13. The dot matrix LED backlighting light source as claimed in claim 12, wherein a packaging area is formed around the multiple LEDs and has two first edge portions oppositely located in the horizontal direction and two second edge portions oppositely located in the vertical direction, two first electrode terminals are respectively formed on the two first edge portions and are respectively connected to two ends of each first electrode of the first electrode assembly, and two second electrode terminals are respectively formed on the two second edge portions and are respectively connected to two ends of each second electrode of the second electrode assembly.

14. A method for fabricating a dot matrix light-emitting diode (LED) backlighting light source for a wafer-level microdisplay, comprising:
providing a first substrate;
growing an LED epitaxial layer on a bottom surface of the first substrate;
forming multiple LEDs out of the LED epitaxial layer through an LED wafer fabrication process;
forming a first electrode assembly on bottom surfaces of the multiple LEDs;
providing a second substrate;
forming a bonding layer on a top surface of the second substrate;
bonding the first electrode assembly of the first substrate to the bonding layer of the second substrate;
removing the first substrate; and
forming a second electrode assembly on top surfaces of the multiple LEDs.

15. The method as claimed in claim 14, wherein the LED wafer fabrication process includes a photolithography process, an etching process, a lift-off process, a thin film deposition process, a coating process, a wafer bonding process, a laser lift-off process, a metal deposition process, and an alloy process.
